(19) United States
(12) Patent Application Publication
(10) Pub. No.: US 2024/0352620 A1
(43) Pub. Date: Oct. 24, 2024

(54) METHOD OF PRODUCING AN EPITAXIALLY COATED SEMICONDUCTOR WAFER OF MONOCRYSTALLINE SILICON

(71) Applicant: SILTRONIC AG, Munich (DE)

(72) Inventors: Karl MANGELBERGER, Ach (AT); Walter HEUWIESER, Stammham (DE)

(21) Appl. No.: 18/683,789

(22) PCT Filed: Aug. 2, 2022
(86) PCT No.: PCT/EP2022/071628

§ 371 Date: Feb. 15, 2024

(30) Foreign Application Priority Data
Aug. 18, 2021 (EP) EP21191891

(51) Int. Cl. C30B 25/20; C30B 15/14; C30B 15/20; C30B 29/06; C30B 30/04

(52) U.S. Cl. CPC C30B 25/20; C30B 15/14; C30B 15/203; C30B 29/06; C30B 30/04

(57) ABSTRACT

A method of producing an epitaxially coated semiconductor wafer of monocrystalline silicon, comprising: providing a melt of silicon in a crucible; pulling a single crystal of silicon from a surface of the melt with a pulling speed v by the CZ method, wherein oxygen and boron are incorporated into the single crystal and the concentration of oxygen in the single crystal is not less than 6.4×10¹⁷ atoms/cm³ and not more than 8.0×10¹⁷ atoms/cm³, and the resistivity of the single crystal is not less than 10 mΩcm and not more than 25 mΩcm, and wherein the melt is not dopes with nitrogen and/or carbon; applying a CUSP magnetic field to the melt during the pulling of the single crystal of silicon, surrounded by a heat shield; controlling the pulling speed v and an axial temperature gradient G at the phase boundary between the single crystal and the melt, in such a way that the quotient v/G is not less than 0.13 mm²/° C. min and not more than 0.20 mm²/° C. min; heating the single crystal by means of an annular heater which is disposed above the melt and surrounds the single crystal; producing a substrate wafer of monocrystalline silicon with a polished lateral surface by processing the single crystal of silicon; and depositing an epitaxial layer of silicon on the polished lateral face of the substrate wafer, wherein the depositing of the epitaxial layer is the first heat treatment in the course of which the substrate wafer is heated to a temperature of not less than 700° C.

### CROSS REFERENCE TO RELATED APPLICATIONS

This application is a U.S. National Phase application under 35 U.S.C. § 371 of International Application No. PCT/EP2022/071628, filed on Aug. 2, 2022, and claims benefit to European Patent Application No. EP21191891, filed on Aug. 18, 2021. The International Application was published in German on Feb. 23, 2023 as WO 2023/020825 A1 under PCT Article 21 (2).

### FIELD

The present disclosure is directed to a method of producing an epitaxially coated semiconductor wafer from monocrystalline silicon, which is especially suitable for further processing to produce electronic components such as complementary metal-oxide semiconductor (CMOS) image sensors (CISs).

### BACKGROUND

Semiconductor wafers, in order to be suitable for producing electronic components such as CISs, should not have metallic impurities that reach the electronic structures accommodated in the epitaxial layer.

US 2014/0374861 A1 states that the presence of oxygen precipitates, called BMDs (bulk microdefects), in the substrate wafer on which the epitaxial layer has been deposited suppresses typical component defects attributable to contamination with metallic impurities, provided that the concentration of BMDs is at least 1.0×10⁹/cm³.

In order to be able to provide such a comparatively high contamination of BMDs, it is frequently suggested that the single crystal that provides the substrate wafer be doped with nitrogen or carbon and/or that the substrate wafer, prior to the deposition of the epitaxial layer, be subjected to a heat treatment that stabilizes nuclei from which BMDs can form at a later stage.

Owing to the doping with nitrogen or carbon, however, surface defects can also arise in the epitaxial layer, and the heat treatment of the substrate wafer constitutes an additional method step that increases manufacturing costs.

DE 10 2014 221 421 B3 describes a method that does not require the doping with nitrogen and does not require any heat treatment prior to the deposition of the epitaxial layer. A disadvantage of this method, however, is that the required BMD density of at least 1.0×10⁹/cm³ is not attained and is not distributed uniformly, but drops toward the edge of the semiconductor wafer with an epitaxial layer.

### SUMMARY

In an embodiment, the present disclosure provides a method that produces an epitaxially coated semiconductor wafer from monocrystalline silicon. The method includes providing a melt of silicon in a crucible; pulling a single crystal of silicon from a surface of the melt with a pulling speed v by the CZ method, oxygen and boron being incorporated into the single crystal and a concentration of the oxygen in the single crystal is not less than 6.4×1017 atoms/cm3 and not more than 8.0×1017 atoms/cm3, and a resistivity of the single crystal is not less than 10 mΩcm and not more than 25 mΩcm, and there being no doping of the melt with nitrogen and carbon; applying a CUSP magnetic field to the melt during the pulling of the single crystal of silicon, surrounded by a heat shield; controlling the pulling speed v and an axial temperature gradient G at a phase boundary between the single crystal and the melt in such a way that a quotient v/G is not less than 0.13 mm2/° C. min and not more than 0.20 mm2/° C. min; heating the single crystal by a ring-shaped heater, which is disposed above the melt and surrounds the single crystal; producing a substrate wafer from the monocrystalline silicon having a polished lateral face by processing the single crystal of silicon; and depositing an epitaxial layer of silicon on the polished lateral face of the substrate wafer. The depositing of the epitaxial layer is a first heat treatment in the course of which the substrate wafer is heated to a temperature of not less than 700° C.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows features of apparatus suitable for executing the method according to aspects of the present disclosure;

FIG. 2 shows the averaged BMD densities of epitaxially coated semiconductor layers produced in accordance with an aspect of the present disclosure after a standard heat treatment, as a function of the relative axial position, depending on the relative axial position (raP) of the corresponding substrate wafers in the single crystal; and

FIG. 3 shows the averaged BMD densities of five epitaxially coated semiconductor wafers produced in accordance with aspects of the present disclosure, depending on the radial position (Pos) at which the BMD densities have been measured.

### DETAILED DESCRIPTION

Aspects of the present disclosure provide a method that provides a semiconductor wafer with an epitaxial layer in which it is possible to generate a BMD density that reaches at least 1.0×10⁹/cm³, including in the edge region thereof.

According to such as aspect, the present disclosure provides a method of producing an epitaxially coated semiconductor wafer from monocrystalline silicon, comprising:
the providing of a melt of silicon in a crucible;
the pulling of a single crystal of silicon from a surface of the melt with a pulling speed v by the CZ method, wherein oxygen and boron are incorporated into the single crystal and the concentration of oxygen in the single crystal is not less than 6.4×10¹⁷ atoms/cm³ and not more than 8.0×10¹⁷ atoms/cm³, and the resistivity of the single crystal is not less than 10 mΩcm and not more than 25 mΩcm, and wherein there is no doping of the melt with nitrogen and carbon;
the applying of a CUSP magnetic field to the melt during the pulling of the single crystal of silicon, surrounded by a heat shield;
the controlling of the pulling speed v and of an axial temperature gradient G at the phase boundary between the single crystal and the melt in such a way that the quotient v/G is not less than 0.13 mm²/° C. min and not more than 0.20 mm²/° C. min;
the heating of the single crystal by means of a ring-shaped heater which is disposed above the melt and surrounds the single crystal;
the producing of a substrate wafer from monocrystalline silicon having a polished lateral face by processing the single crystal of silicon; and
the depositing of an epitaxial layer of silicon on the polished lateral face of the substrate wafer, wherein the depositing of the epitaxial layer is the first heat treatment in the course of which the substrate wafer is heated to a temperature of not less than 700° C.

An epitaxially coated semiconductor wafer of monocrystalline silicon that has p/p+ doping and has been produced by this method is particularly suitable for the production of CIS components, especially owing to the radially homogeneous BMD distribution that can be generated by means of a heat treatment beneath the epitaxial layer. The heat treatment preferably comprises the heating of the epitaxially coated semiconductor wafer first to a temperature of 780° C. over a period of 3 h and then to a temperature of 1000° C. over a period of 16 h. Alternatively, it is also possible to conduct a heat treatment with a comparable thermal budget in the course of further processing of the epitaxially coated semiconductor wafer to give electronic components.

The single crystal from which the substrate wafer that is epitaxially coated in the course of the method is divided is produced by the magnetic Czochralski (MCZ) method, wherein the single crystal is pulled using a seed crystal from a melt which is generated in a crucible and is subjected to a magnetic field. The magnetic field used in an axially symmetric magnetic field, a CUSP magnetic field. The CUSP magnetic field attains a maximum field strength of preferably not less than 105 mT and not more than 116 mT, with the plane of the CUSP magnetic field having a field strength of 0 mT being preferably not less than 30 mm and not more than 80 mm, more preferably 50 mm, below the surface of the melt.

The single crystal is preferably cooled actively. The cooling rate in the temperature range from 1000° C. to 800° C. is preferably not less than 0.7° C./min and not more than 1° C./min.

The distance of a lower edge of the heat shield from the surface of the melt is preferably not less than 35 mm and not more than 45 mm.

The amount of oxygen that gets into the single crystal in the course of pulling off the single crystal is controlled via the adjustment of process parameters. These process parameters especially include the strength of the CUSP magnetic field, the speed of rotation of the crucible, and the pressure of the purge gas which is passed over the melt in order to remove silicon dioxide escaping from the melt from the environment of the single crystal. The speed of rotation of the crucible is preferably not less than 3.5 rpm and not more than 6.0 rpm. The pressure of the purge gas, for example of argon, hydrogen or a mixture of the two gases, is preferably not less than 2500 Pa and not more than 8500 Pa.

The point defect distribution in the single crystal has a particular influence on the ability of BMDs to form later in the epitaxially coated semiconductor wafer. As is well known, the point defect distribution depends on the value that the quotient v/G had during the pulling of the single crystal. Material factors are accordingly the ratio of pulling speed v and the axial temperature gradient G, and the phase boundary between the growing single crystal on the melt. The method according to the present disclosure requires a quotient v/G of not less than 0.13 mm²/° C. min and not more than 0.20 mm²/° C. min. The pulling speed is preferably not less than 0.4 mm/min and not more than 0.48 mm/min.

The axial temperature gradient G in the edge region of the growing single crystal is additionally influenced by the heating of the single crystal by means of a ring-shaped heater which is disposed above the melt and surrounds the single crystal. For a single crystal having a diameter of 300 mm, the power of the ring-shaped heater is preferably not less than 7 kW and not more than 13 kW.

The pulled single crystal has a diameter of preferably at least 200 mm, more preferably at least 300 mm, and is processed to give substrate wafers of monocrystalline silicon. The operating steps include, as well as the dividing of the single crystal into wafers, further mechanical processing steps such as the lapping and/or grinding of the lateral faces of the wafers and the rounding off the edges of the wafers. The substrate wafers are preferably also chemically etched and especially chemically-mechanically polished. A substrate wafer therefore has a polished edge and at least one polished lateral face. Preferably, the polishing steps comprise the simultaneous polishing (DSP) of the front and reverse faces of the substrate wafer and the polishing (CMP) of the front face of the substrate wafer.

The epitaxial layer of silicon is preferably deposited on the polished front face of the substrate wafer. This step is preferably conducted in a single-wafer reactor, for example in a reactor of the Centura® type supplied by Applied Materials. The deposition gas preferably contains a hydrogen-containing silane, for example trichlorosilane (TCS). The deposition temperature, when TCS is used, is within a temperature range of preferably not less than 1000° C. and not more than 1250° C. The thickness of the epitaxial layer is preferably at least 1 μm. The depositing of the epitaxial layer is the first heat treatment in the course of which the substrate wafer is heated to a temperature of not less than 700° C. Prior to the depositing of the epitaxial layer, there is thus no heat treatment for nucleation of the BMD seeds. The substrate wafer is also not intentionally doped with nitrogen and/or carbon.

The epitaxially coated semiconductor wafer of monocrystalline silicon thus produced, in the region of the substrate wafer, has the concentration of interstitial oxygen and the resistivity of the single crystal from which the substrate wafer originates. The concentration of oxygen is accordingly not less than 6.4×10¹⁷ atoms/cm³ and not more than 8.0×10¹⁷ atoms/cm³ (according to the standard new ASTM), and the resistivity is not less than 10 mΩcm and not more than 25 mΩcm.

If the epitaxially coated semiconductor wafer of monocrystalline silicon is subjected to a standard heat treatment comprising heating to a temperature of 780° C. over a period of 3 h and then to a temperature of 1000° C. over a period of 16 h, or a heat treatment with a comparable thermal budget, BMDs are formed beneath the epitaxial layer with a density of at least 1×10⁹/cm³, in a radially homogeneous distribution. The variation in the BMD density over the radius is less than 170%, calculated by the formula ((BMDmax−BMDmin)/BMDmean)×100%, where BMDmax, BMDmin and BMDmean denote the measured greatest, smallest and average BMD density.

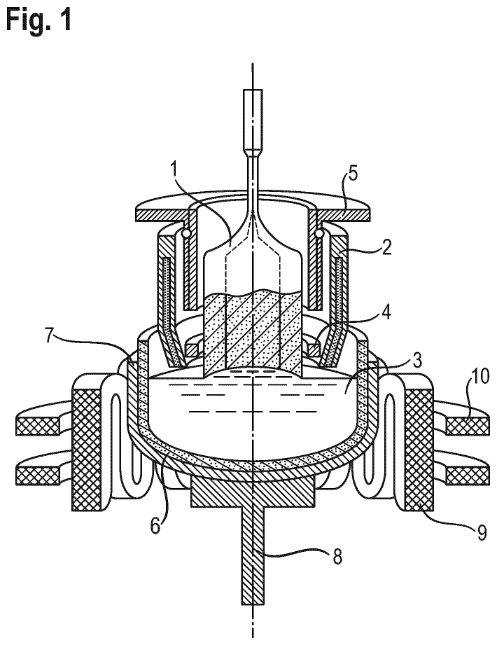

FIG. 1 shows the schematic diagram of the immediate environment (hot zone) of the single crystal during production thereof, with use of an apparatus suitable for performance of the method according to the present disclosure. The growing single crystal 1 is surrounded by a heat shield 2, the lower end of which is at a short distance from the melt 3. Additionally present in the region of the lower end of the heat shield 2 is a ring-shaped heater 4, which supplies the heat to the edge of the phase boundary between the single crystal 1 and the melt 3. The ring-shaped heater 4 assists the control of the temperature gradient at the edge of the phase boundary between the growing single crystal 1 and amount 3, and is preferably also part of a control system for the diameter of the single crystal. At the level of the middle and upper region of the heat shield 2 and at a certain distance from the ring-shaped heater 4, the single crystal 1 is also surrounded by a device 5 for cooling the single crystal, preferably a water-cooled cooler. The melt 3 is present in a crucible 6 made of quartz, which is in turn held by an outer crucible 7 made of graphite. The crucibles 6, 7 and the melt 3 rest on an end of a rotatable, liftable and lowerable shaft 8. The melt 3 is supplied mainly with heat via a resistance heater 9, disposed around the outer crucible 7. A device 10 for generating the CUSP magnetic field which is applied to the melt 3 surrounds the resistance heater 9 in turn.

Multiple single crystals of silicon were pulled in an accordance with the present disclosure in a device having the features shown in FIG. 1 and processed further to give epitaxially coated semiconductor wafers having a diameter of 300 mm.

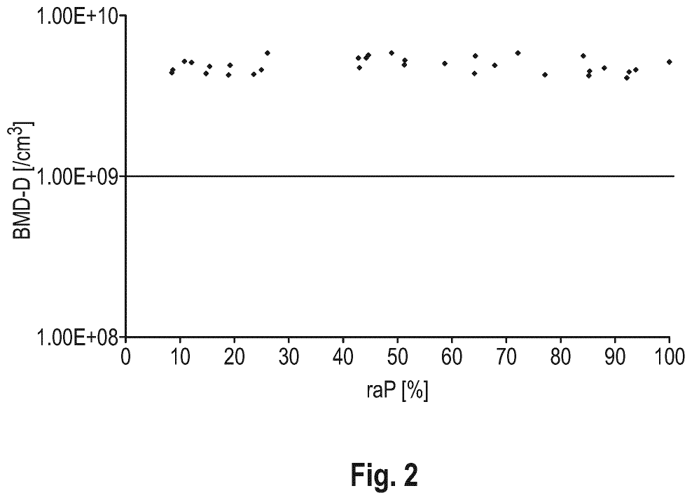

FIG. 2 shows the averaged BMD densities (BMD-D) of the semiconductor wafers, which were produced in accordance with a method of the present disclosure after a standard heat treatment, as a function of the relative axial position (raP) of the corresponding substrate wafers in the single crystal.

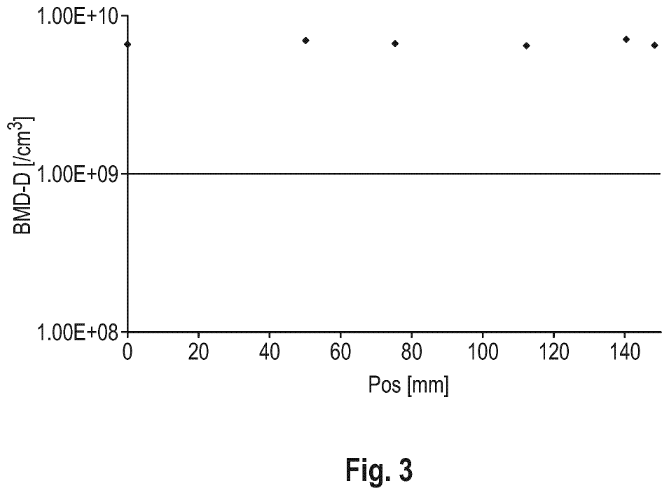

FIG. 3 shows the averaged BMD densities (BMD-D) of five of the epitaxially coated semiconductor wafers produced in accordance with the present disclosure depending on the radial position (Pos) at which the BMD densities have been measured.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS USED

1 single crystal
2 heat shield
3 melt
4 ring-shaped heater
5 device for cooling the single crystal
6 crucible
7 outer crucible
8 shaft
9 resistance heater
10 device for generation of a CUSP magnetic field

1. A method of producing an epitaxially coated semiconductor wafer from monocrystalline silicon, the method comprising:
providing a melt of silicon in a crucible;
pulling a single crystal of silicon from a surface of the melt with a pulling speed v by the CZ method, wherein oxygen and boron are incorporated into the single crystal and a concentration of the oxygen in the single crystal is not less than 6.4×10¹⁷ atoms/cm³ and not more than 8.0×10¹⁷ atoms/cm³, and a resistivity of the single crystal is not less than 10 mΩcm and not more than 25 mΩcm, and wherein there is no doping of the melt with nitrogen and carbon;
applying a CUSP magnetic field to the melt during the pulling of the single crystal of silicon, surrounded by a heat shield;
controlling the pulling speed v and an axial temperature gradient G at a phase boundary between the single crystal and the melt in such a way that a quotient v/G is not less than 0.13 mm²/° C. min and not more than 0.20 mm²/° C. min;
heating the single crystal by a ring-shaped heater, which is disposed above the melt and surrounds the single crystal;
producing a substrate wafer from the monocrystalline silicon having a polished lateral face by processing the single crystal of silicon; and
depositing an epitaxial layer of silicon on the polished lateral face of the substrate wafer, wherein the depositing of the epitaxial layer is a first heat treatment in the course of which the substrate wafer is heated to a temperature of not less than 700° C.

2. The method according to claim 1, further comprising cooling the single crystal pulled from the melt at a cooling rate within a temperature range from 1000° C. to 800° C., which is not less than 0.7° C./min and not more than 1° C./min.

3. The method according to claim 1, wherein a distance of a lower edge of the heat shield from the surface of the melt is not less than 35 mm and not more than 45 mm.

4. The method according to claim 1, wherein the CUSP magnetic field attains a maximum field strength of not less than 105 mT and not more than 116 mT, and a plane of the CUSP magnetic field with a field strength of 0 mT is not less than 30 mm and not more than 80 mm below the surface of the melt.

5. The method according to claim 1, further comprising rotating the crucible at a speed of less than 3.5 rpm and not more than 6.0 rpm.

6. The method according to claim 1, wherein the pulling of the single crystal is in an atmosphere of purge gas, a pressure of which is not less than 2500 Pa and not more than 8500 Pa.

7. The method according to claim 1, wherein the single crystal has a diameter of 300 mm, and a power of the ring-shaped heater is not less than 7 kW and not more than 13 kW.
